(19) United States
(12) Patent Application Publication
(10) Pub. No.: US 2010/0068658 A1
(43) Pub. Date: Mar. 18, 2010

(54) PHOTOLITHOGRAPHIC PATTERNING OF ARRAYS OF PILLARS HAVING WIDTHS AND LENGTHS BELOW THE EXPOSURE WAVELENGTHS

(75) Inventors: Fenghong Zhang, Synnyvale, CA (US); Jian Xu, San Jose, CA (US); Xinyu Zhang, Palo Alto, CA (US); Ching-Hwa Chen, Milpitas, CA (US); Leu Mei, San Jose, CA (US)

Correspondence Address: Haynes and Boone, LLP;IP Section, 2323 Victory Avenue, SUITE 700, Dallas, TX, 75219, US

(73) Assignee: ProMOST Technologies Pte.Ltd.

(21) Appl. No.: 12/233,298

(22) Filed: Sep. 18, 2008

(51) Int. Cl. G03F 7/20

(52) U.S. Cl. 430/325

(57) ABSTRACT

A pillar array is printed in positive photoresist using an optical mask (108) having an array of features (310) corresponding to the pillars. The pillars' width/length dimensions are below the exposure wavelength. Superior results can be achieved (less peeling off of the pillars and less overexposure at the center of each pillar) if the mask features (310) are downsized relative to the pillars' target sizes, and the exposure energy is reduced. Negative photoresist (with a dark field mask) can be used, and can provide good results (in terms of pillars peeling-off) if the combined area of the features (410) corresponding to the pillars is smaller than the area between the features (410).

### BACKGROUND OF THE INVENTION

The present invention relates to photolithography, and more particularly to forming arrays of pillars whose widths and lengths are below the exposure wavelengths.

In a photolithographic exposure process, a wafer surface is coated with photoresist, and the photoresist is illuminated by light passing through an optical mask having a pattern of clear and opaque features. These features define an illumination pattern of light and dark areas on the photoresist surface. At the light areas, the photoresist becomes more soluble (if positive) or less soluble (if negative) in a developer solution. The wafer is then placed into the developer solution to dissolve the soluble portions of the photoresist. The remaining photoresist provides a mask for subsequent processing (e.g. etching, deposition, ion implantation, etc.).

In non-contact photolithographic exposure, the optical mask is held at a distance from the photoresist surface to avoid mask damage. Due to bending of light rays, the pattern of light and dark areas in the photoresist does not always correspond to the pattern of clear and opaque features of the optical mask. The photoresist areas corresponding to the opaque features can thus be undesirably illuminated, reducing the contrast between the dark and light areas. The contrast is particularly low when the dark areas in the photoresist are small, e.g. below the light's wavelength (“exposure wavelength”). To darken the dark areas for better contrast, opaque features can be enlarged on the mask (e.g. with serifs or hammerheads). The contrast can also be sometimes improved by increasing the exposure dose (i.e. the light intensity per unit area of the mask).

The contrast obtained in photolithographic exposure depends on sizes and other geometric characteristics of the pattern to be formed in photoresist. Techniques which help improve contrast with one type of pattern (e.g. a pattern of lines and spaces) will not necessarily work for another kind of pattern. One type of pattern commonly used in memory products is an array of pillars. Pillars are common structures in Static Random Access Memory (SRAM), Phase-change Random Access Memory (PRAM) and Magnetoresistive Random Access Memory (MRAM).

### SUMMARY

This section summarizes some features of the invention. Other features may be described in the subsequent sections. The invention is defined by the appended claims, which are incorporated into this section by reference.

The inventors have attempted to pattern positive photoresist into an array of pillars whose widths and lengths are below the exposure wavelength. The inventors used an optical mask having opaque features sized to correspond to the pillars' target sizes. More particularly, an exposure system may use a lens which shrinks the mask features by some “shrinkage factor” (e.g. 4 or 5). The opaque features had sizes equal to the target sizes of the pillars times the shrinkage factor. The inventors discovered that if the pillars' target sizes are below the exposure wavelength, then the pillars may peel off when the photoresist is being developed. The inventors attempted to enlarge the opaque features and increase the exposure energy dose for better contrast, but discovered that superior results may be achieved, on the contrary, by downsizing the opaque features and decreasing the exposure dose. Thus, in some embodiments of the invention, the opaque features' widths and lengths are below the values defined by the target sizes (which are below the exposure wavelength), and the energy dose is smaller than needed for the opaque features sized at the target size times the shrinkage factor. The photoresist is less prone to peeling off, possibly due to the lower energy doze.

These embodiments of the invention use positive photoresist, and hence a clear field mask. The inventors believe that in some embodiments, superior results may be achieved with a negative photoresist (i.e. with a dark field mask) if at least in the array region, the wafer area illuminated with the dark field mask would be smaller than with the clear field mask (i.e. if the combined area of the pillars is smaller than the area between the pillars). For example, if the spacing between the adjacent pillars is three times the pillar size and the pillars' target widths and lengths are below the wavelength, then the dark field mask may be preferable.

The invention is not limited to the features and advantages described above except as defined by the appended claims.

### BRIEF DESCRIPTION OF THE DRAWINGS

FIG. 1 is a side view of an exemplary photolithographic exposure system used to form an illumination pattern on a wafer.

FIG. 2A is a plan view of an optical mask according to prior art.

FIG. 2B is a plan view of a photoresist pattern formed using the optical mask of FIG. 2A.

FIG. 3A is a plan view of an optical mask according to some embodiments of the present invention.

FIG. 3B is a plan view of a photoresist pattern formed using the optical mask of FIG. 3A.

FIG. 4A is a plan view of a dark-field optical mask according to some embodiments of the present invention.

FIG. 4B is a plan view of a photoresist pattern formed using the optical mask of FIG. 4A.

### DESCRIPTION OF SOME EMBODIMENTS

The embodiments described in this section illustrate but do not limit the invention. The invention is defined by the appended claims.

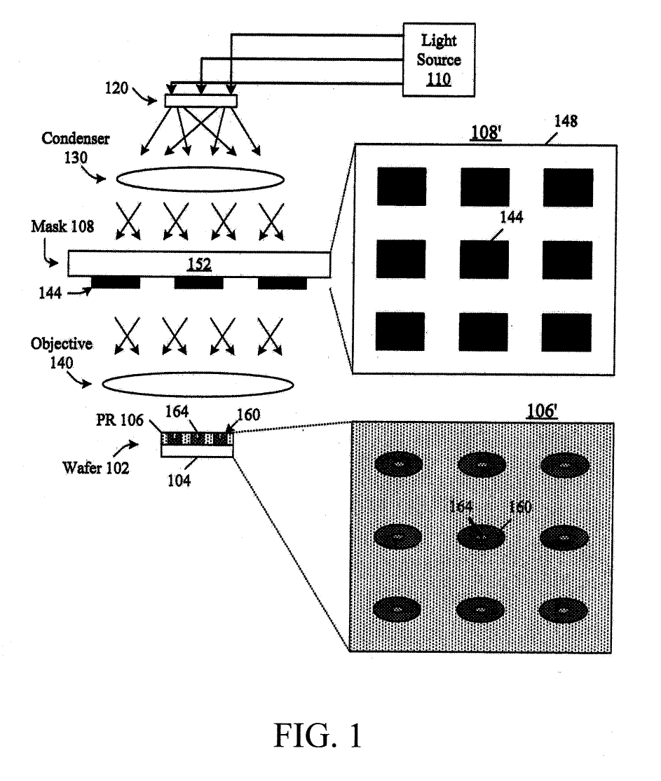

FIG. 1 is a side view of an exemplary photolithographic exposure system used to form an illumination pattern on a wafer. The wafer 102 includes a substrate 104 covered with a photoresist layer 106. The system is projection type, with optical mask 108 being at a distance from the wafer. Coherent light emitted by a laser light source 110 passes through an illumination pupil 120 positioned in the focal plane of a condenser lens 130. The light emerging from pupil 120 is coherent or partially coherent. Condenser lens 130 concentrates the light on the mask 108. Objective lens 140 images the pattern of mask 108 onto the photoresist 106. Objective 140 may also shrink the mask pattern (by a factor S of four or five for example). A suitable exposure system is type ASML XT 1250 (Trademark) available from ASML Holding N.V., De Run 6501, 5504 D R Veldhoven, The Netherlands, with the light wavelength λ=193 nm. The invention is not limited to a particular exposure system or wavelength.

Mask 108 is shown in plan view at 108′. The view 108′ may represent only a portion of the mask, and the mask may be projected onto only a portion of wafer 102, as is done in some stepper-type exposure systems. The mask 108 contains an array of opaque features 144 surrounded by clear feature 148 bordering on each opaque feature 144. This type of mask can be provided by a clear substrate 152, with features 144 formed on substrate 152 using an opaque material (e.g. chrome) or a partially transparent material (e.g. molybdenum silicon (MoSi), used in attenuated phase-shift masks (APSMs)). Features 144 thus can be partially opaque, but will be called “opaque” in the sense that they are more opaque to light from source 110 than the clear feature 148.

The corresponding pattern of light and dark areas in photoresist 106 is shown in plan view at 106′. The view 106′ is sized to the dimensions of view 108′ (i.e. the view 106′ is enlarged by the shrinkage factor S if S is not 1). Each opaque feature 144 is projected onto a respective photoresist area 160. The inventors have discovered that depending on the dimensions of the features 144, a photoresist area 160 may be not all dark but may contain a light area 164 at the center.

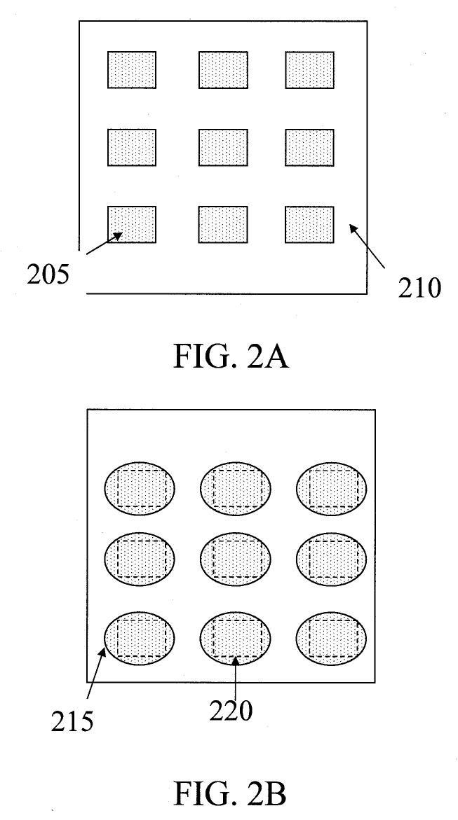

FIG. 2A is a plan view of an optical mask in a “normal size”, i.e. with features sized to correspond to target dimensions on the wafer. The mask is used to pattern an array of pillars (FIG. 2B) having widths and lengths below the exposure wavelength. The mask comprises normal-sized opaque features 205 and clear feature 210. The mask may be made using a substrate of clear quartz. Opaque features 205 may be made of chrome for binary masks or of MoSi for APSMs. The invention is not limited to particular materials or types of masks. In FIG. 2A, the opaque features 205 are rectangular but other shapes are also possible. The feature 205 dimensions are obtained by multiplying the target dimensions by a shrinkage factor which accounts for the shrinkage of the mask features by the objective lens 140 (FIG. 1). For example, if the shrinkage factor is 4, and the target width and length are 130 nm×130 nm, then each feature 205 is 130*4=520×520 nm. The exposure wavelength is 193 nm in some embodiments. The array may have any number of rows and columns, e.g. 512×512, 1024×1024, 2048×2048, or some other number.

In some embodiments, the distance between the adjacent pillars in each row and each column is one to three times the pillar dimension (e.g. the distance is 130 nm to 390 nm for 130×130 nm pillars; if the shrinkage factor is 4, then the distance between adjacent features 205 is 130*4=520 nm to 390*4=1560 nm).

FIG. 2B is a plan view of the photoresist pattern of pillars 215 obtained on wafer 120 with the mask of FIG. 2A using the exposure system of FIG. 1 with the wavelength λ=193 nm. The energy dose is 28.5 mJ/cm². The wafer distance F from the best focus position is within ±0.05 μm (the F distance is positive if the wafer is closer to objective lens 140 than the best focus position; F<0 if the wafer is farther from the objective lens than the best focus position). Target-size rectangles 220 (e.g. 130 nm×130 nm) are images of rectangles 205 and shown with dotted lines. The actual photoresist pillars 215 corresponding to the features 205 are slightly larger than the corresponding target-size rectangles 220.

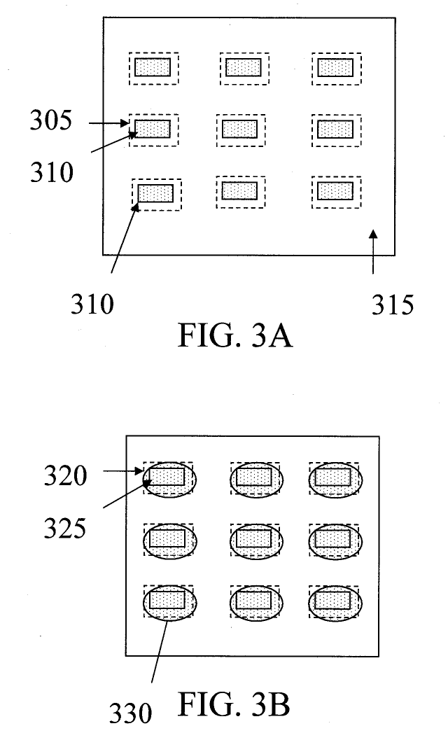

FIG. 3A is a plan view of an optical mask with “negatively sized” features 310, i.e. with features 310 reduced below the dimensions corresponding to the target sizes (below the target sizes times the shrinkage factor), designed to form the pillars as in FIG. 2B. The features 305 are the corresponding normal-sized rectangular features (the same as features 205 in FIG. 2A) and are shown by dotted line.

Each negatively-sized opaque feature 310 is smaller than, and fits within (is concentric to), the normal-sized opaque feature 305. In some embodiments, the target size of each pillar is 130×130 nm, the target distance between the pillars is 130 nm to 390 nm, the shrinkage factor S=4, the exposure wavelength is 193 nm, and the width and length dimensions of each negatively-sized opaque feature 310 are 440×440 nm. These dimensions correspond to 110×110 nm pillar dimensions. Thus, the “wafer-level” width and length of each opaque feature 310 (i.e. the width and length without taking the shrinkage factor into account) is 20 nm less than the 130 nm dimensions of FIG. 2A.

The clear feature 315 is enlarged compared to FIG. 2A. The invention is not limited to the rectangular shapes.

FIG. 3B is a plan view of the photoresist pattern obtained on the wafer using the mask of FIG. 3A and the exposure system of FIG. 1 with the wavelength of 193 nm. The energy dose is 22.5 mJ/cm². The wafer distance F from the best focus position is in the range from −0.05 μm to 0.1 μm inclusive. The target-size rectangles 320 are shown by dotted lines. These rectangles are images of rectangles 305 of FIG. 3A. The negatively-sized rectangles 325 are images of features 310. The photoresist pillars 330 are slightly larger than rectangles 325. The invention is not limited to rectangles.

### EXAMPLE 1

Some embodiments use the ASML XT 1250 exposure tool with the 193 nm wavelength and the shrinkage factor S=4. These embodiments are directed to the target pillar size of 180 nm×180 nm. The target distance between the adjacent pillars is 180 nm to 540 nm. The pillar array has at least 512 rows and at least 512 columns (the number of rows and columns can be 1024 or any other number above or below 512). The inventors formed pillars with a mask of FIG. 2A and with a mask of FIG. 3A. Both masks were attenuated phase shift masks. In the mask of FIG. 2A, feature sizes corresponded to the target sizes. In particular, each opaque feature 205 was 180*4=720 nm×720 nm in size. A number of experiments were performed with this mask to determine the best exposure energy and the depth of focus. The best exposure energy was 33 mJ/cm². The depth of focus at this energy was 0.2 μm.

In the mask of FIG. 3A, the wafer-level size of each opaque feature 310 was 160 nm×160 nm (i.e. the actual size was 640×640 nm). The best exposure energy was 27 mJ/cm². The depth of focus at this energy was 0.2 μm.

### EXAMPLE 2

Another set of similar experiments were performed for the target pillar size of 130 nm×130 nm and the target distance between the adjacent pillars of 420 nm. The number of rows and columns in the pillar array was as for the 180×180 nm experiments. In the mask of FIG. 2A, feature sizes corresponded to the target sizes. In particular, each opaque feature 205 had a wafer-level size of 130×130 nm, i.e. the actual size of 420 nm×420 nm. The best exposure energy was 28.5 mJ/cm². The depth of focus at this energy was 0.1 μm. More particularly, acceptable pillars, with dimensions ranging from about 131×131 nm to 142×142 nm, were obtained at the wafer positions in the range BF±0.05 μm, where BF is the best focus position. The exposure latitude at the BF position was 7.8 mj/cm².

In the mask of FIG. 3A, the wafer-level size of each opaque feature 310 was 110 nm×110 nm, i.e. the actual size was 440×440 nm. The best exposure energy was 22.5 mJ/cm². The depth of focus was improved to 0.15 μm because acceptable pillars, with dimensions ranging from about 121×121 nm to 131×131 nm, were obtained at the wafer positions in the range from BF−0.05 μm to BF+0.1 μm. The exposure latitude at the BF position improved to 13.3 mj/cm².

Thus, reducing the feature sizes and the exposure energy improves the depth of focus and the exposure latitude.

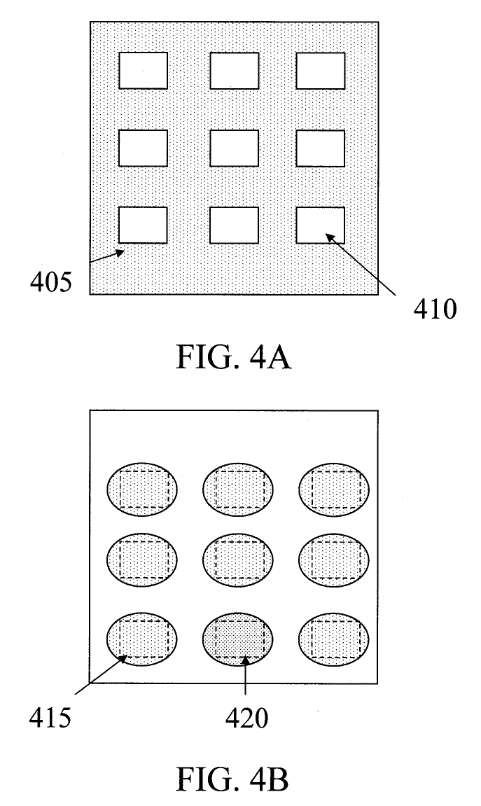

FIG. 4A is a plan view of a dark-field optical mask for use with negative photoresist. In FIG. 4A, the features 410 are an array of clear features. The features 410 are surrounded by an opaque region 405. The dimensions of rectangles 410, the spacing therebetween, and the number of rows and columns of rectangles 410 can be as for features 305 or 310 in FIG. 3A, or for features 205 in FIG. 2A. In some embodiments, the combined area occupied by features 410 is smaller than the area of opaque region 405, and hence the exposure energy reaching the photoresist is lower than with a clear field mask (assuming equal energies emitted by light source 110 during the exposure). Hence, the erosion of photoresist pillars is less likely to occur. In particular, the photoresist pillars are less likely to erode in areas 164 (FIG. 1).

FIG. 4B is a plan view of a photoresist pattern obtained on the wafer using the mask of FIG. 4A and the exposure system of FIG. 1. The exposure wavelength is higher than the length of each feature 410 and than the width of each feature 410. Rectangles 420, shown by dotted line, are images of the clear features 410. Photoresist pillars 415 are slightly larger than the rectangles 420.

Some embodiments of the present invention provide a method for photolithographically patterning photosensitive material with light comprising a wavelength λ to which the material is sensitive, to form a pillar array in the photosensitive material. The photosensitive material may be photoresist, polyimide, or possibly some other type of material. The method comprises operations (a), (b), (c) defined as follows. The operation (a) consists in obtaining an optical mask comprising a feature array which is an array of first features (e.g. 310) to be projected onto the respective pillars, the first features being less transparent to said light than the optical mask's portion between the first features. In FIG. 3A, the feature array is rectangular, and each feature 310 is rectangular, but this is not necessary. The operation (b) consists in illuminating the photosensitive material with said light passing through the optical mask to project each first feature onto a site of a respective one of said pillars, the projection being performed with a shrinkage factor S wherein the shrinkage factor S is a positive number smaller than one (in case of magnification), equal to one (in case of no shrinkage and no magnification), or larger than one (in case of shrinkage), the light causing the photosensitive material between the pillars' sites to become less resistant to a developing operation in which the photosensitive material is to be developed.

Then the operation (c) is performed which consists in performing the developing operation to remove at least part of the photosensitive material from between the pillars' sites thus forming said pillars. Each pillar's width is larger than the respective first feature's wafer-level width (which is the first feature's width divided by the shrinkage factor S) by at least 10% of the respective first feature's wafer-level width, and each pillar's length is larger than the respective first feature's wafer-level length (which is the first feature's length divided by the shrinkage factor S) by at least 10% of the respective first feature's wafer-level length. For example, suppose the pillars are 130×130 nm, and the wafer-level dimensions of the features 310 are 110×110 nm. Then 10% the features' wafer-level length is 11 nm. The pillar length of 130 nm is greater than the features' wafer-level length of 110 nm by 130−110=20 nm, which is more than 10% of the wafer-level length of features 310.

If a feature 310 is not rectangular, then the “width” and “length” can be defined as follows. Each feature 310 is part of a row and a column of the feature array. The “width” of feature 310 can be defined as the dimension through the feature 310 along the array row (e.g. horizontally), and the “length” can be defined as the dimension along the array column (e.g. vertically). Of course, “length” and “width” are interchangeable. If the feature includes an inside clear portion, then the “length” and the “width” may be measured through the clear inside portion.

If the feature array is not rectangular (e.g. the rows are not straight but curved, and/or the columns are curved), then the width and length are measured along the row and column directions at the feature's location, i.e. along the directions which the row and column have at the feature's location.

In some embodiments, the distance between any two adjacent pillars in the direction of the pillars' widths is one to four times as large as the adjacent pillars' largest width. For example, if the target width is 130 nm and two adjacent pillars have widths of 121 nm and 123 nm respectively, then the distance between the pillars in the width direction is at least 123 nm and at most 123*4=492 nm.

Likewise, in some embodiments, the distance between any two adjacent pillars in the direction of the pillars' lengths is one to four times as large as the adjacent pillars' largest length.

In some embodiments, the distance between any two adjacent first features in the direction of the first features' widths is one to four times as large as the adjacent first features' widths. For example, if the target width of each pillar is 130 nm, the shrinkage factor is 4, and each negatively-sized feature 310 has a width of 110*4=440 nm, then the distance between the adjacent features 310 is at least 440 nm and at most 440*4=1,760 nm.

Likewise, in some embodiments, the distance between any two adjacent first features in the direction of the first features' lengths is one to four times as large as the adjacent first features' lengths.

In some embodiments, said light is provided to said mask at a first exposure dose smaller than a best exposure dose needed to form pillars with an optical mask having the first features' widths and lengths enlarged by at least 10%. For instance, in example 1 described above, for the 160×160 nm wafer-level size of opaque features 310, the exposure dose (“first exposure dose”) was 27 mJ/cm². When the feature 310 sizes were increased by at least 10%, i.e. to the wafer-level size of 180×180 nm, then the best exposure dose increased to 33 mJ/cm².

In some embodiments, the first exposure dose is smaller than said best exposure dose by at least 10% of said best exposure dose (e.g. 27 mJ/cm² is smaller than 33 mJ/cm² by more than 10% of 33 mJ/cm², i.e. by more than 3.3 mJ/cm²).

In some embodiments, the first exposure dose is smaller than said best exposure dose by at least 20% of said best exposure dose (as in Example 2).

In some embodiments, the wavelength λ is at most 248 nm, or at most 193 nm, or in some other range.

Some embodiments provide a method for photolithographically patterning photosensitive material with light comprising a wavelength λ to which the material is sensitive, to form a pillar array in the photosensitive material, the method comprising: obtaining data defining a target width and length of each pillar (e.g. 130×130 nm in Example 2), the target width and length of each pillar being below the wavelength λ; obtaining an optical mask comprising a feature array which is an array of first features (e.g. 310) to be projected onto the respective pillars, the first features being less transparent to said light than the optical mask's portion between the first features, wherein each first feature's wafer-level width is below the target width of the respective pillar, and wherein each first feature's wafer-level length is below the target length of the respective pillar; illuminating the photosensitive material with said light passing through the optical mask to project each first feature onto a site of a respective one of said pillars; and then performing the developing operation to remove at least part of the photosensitive material from between the pillars' sites thus forming said pillars.

In some embodiments, each first feature's wafer-level width (e.g. 110 nm) is smaller than the target width of the respective pillar (e.g. 130 nm) by more than 10% of the target width of the respective pillar (e.g. by more than 13 nm), and each first feature's wafer-level length is smaller than the target length of the respective pillar by more than 10% of the target length of the respective pillar.

In some embodiments, each first feature's wafer-level width is smaller than the target width of the respective pillar by less than 20% of the target width of the respective pillar, and each first feature's wafer-level length is smaller than the target length of the respective pillar by less than 20% of the target length of the respective pillar.

In some embodiments, the target distance between any two adjacent pillars in the direction of the pillars' widths is one to three times as large as the adjacent pillars' largest target width. For example, if the target width is 130 nm, then the target distance between the adjacent pillars may be 130 nm to 130*3=390 nm. In some embodiments, the target distance between any two adjacent pillars in the direction of the pillars' lengths is one to three times as large as the adjacent pillars' largest target length.

In some embodiments, the target width and length of each pillar are each in the range of 130 nm to 180 nm, each first feature's wafer-level width is smaller than the target width of the respective pillar by at least 20 nm, and each first feature's wafer-level length is smaller than the target length of the respective pillar by at least 20 nm.

Some embodiments provide a method for photolithographically patterning photosensitive material with light comprising a wavelength λ to which the material is sensitive, to form a pillar array in the photosensitive material, the method comprising: (a) obtaining an optical mask comprising a feature array which is an array of first features (e.g. 410) which are more transparent to said light than the optical mask's portion between the first features, wherein each said first feature's wafer-level width and length are below the wavelength λ, and wherein a combined area of the first features is smaller than the feature array's area between the first features; (b) illuminating the photosensitive material with said light passing through the optical mask to project each first feature onto a site of a respective one of said pillars, the light causing the photosensitive material at the pillars' sites to become resistant to a developing operation developing the photosensitive material; and then (c) performing the developing operation to remove at least part of the photosensitive material from between the pillar sites thus forming said pillars.

The invention is not limited to the embodiments described above except as defined by the appended claims.

1. A method for photolithographically patterning photosensitive material with light comprising a wavelength λ to which the material is sensitive, to form a pillar array in the photosensitive material, the method comprising:
(a) obtaining an optical mask comprising a feature array which is an array of first features to be projected onto the respective pillars, the first features being less transparent to said light than the optical mask's portion between the first features;
(b) illuminating the photosensitive material with said light passing through the optical mask to project each first feature onto a site of a respective one of said pillars, the projection being performed with a shrinkage factor S wherein the shrinkage factor S is a positive number smaller than one (in case of magnification), equal to one (in case of no shrinkage and no magnification), or larger than one (in case of shrinkage), the light causing the photosensitive material between the pillars' sites to become less resistant to a developing operation in which the photosensitive material is to be developed; and then
(c) performing the developing operation to remove at least part of the photosensitive material from between the pillars' sites thus forming said pillars, wherein each said pillar's width is larger than the respective first feature's wafer-level width (which is the first feature's width divided by the shrinkage factor S) by at least 10% of the respective first feature's wafer-level width, and each said pillar's length is larger than the respective first feature's wafer-level length (which is the first feature's length divided by the shrinkage factor S) by at least 10% of the respective first feature's wafer-level length.

2. The method of claim 1 wherein a distance between any two adjacent pillars in a direction of the pillars' widths is one to four times as large as the adjacent pillars' largest width; and
a distance between any two adjacent pillars in a direction of the pillars' lengths is one to four times as large as the adjacent pillars' largest length.

3. The method of claim 1 wherein a distance between any two adjacent first features in a direction of the first features' widths is one to four times as large as the adjacent first features' widths; and
a distance between any two adjacent first features in a direction of the first features' lengths is one to four times as large as the adjacent first features' lengths.

4. The method of claim 1 wherein in the operation (b), said light is provided to said mask at a first exposure dose smaller than a best exposure dose needed to form pillars with an optical mask having the first features' widths and lengths enlarged by at least 10%.

5. The method of claim 4 wherein the first exposure dose is smaller than said best exposure dose by at least 10% of said best exposure dose.

6. The method of claim 5 wherein the first exposure dose is smaller than said best exposure dose by at least 20% of said best exposure dose.

7. The method of claim 1 wherein the wavelength λ is at most 248 nm.

8. The method of claim 7 wherein the wavelength λ is at least 193 nm.

9. The method of claim 1 wherein the wavelength λ is at most 193 nm.

10. The method of claim 9 wherein each first feature's wafer-level width and length is at most 160 nm.

11. The method of claim 1 wherein the feature array is rectangular.

12. The method of claim 1 wherein each first feature is rectangular.

13. A method for photolithographically patterning photosensitive material with light comprising a wavelength λ to which the material is sensitive, to form a pillar array in the photosensitive material, the method comprising:
obtaining data defining a target width and length of each pillar, the target width and length of each pillar being below the wavelength λ;
obtaining an optical mask comprising a feature array which is an array of first features to be projected onto the respective pillars, the first features being less transparent to said light than the optical mask's portion between the first features, wherein each first feature's wafer-level width is below the target width of the respective pillar, and wherein each first feature's wafer-level length is below the target length of the respective pillar;
illuminating the photosensitive material with said light passing through the optical mask to project each first feature onto a site of a respective one of said pillars; and then
performing the developing operation to remove at least part of the photosensitive material from between the pillars' sites thus forming said pillars.

14. The method of claim 13 wherein each first feature's wafer-level width is smaller than the target width of the respective pillar by more than 10% of the target width of the respective pillar, and each first feature's wafer-level length is smaller than the target length of the respective pillar by more than 10% of the target length of the respective pillar.

15. The method of claim 14 wherein each first feature's wafer-level width is smaller than the target width of the respective pillar by less than 20% of the target width of the respective pillar, and each first feature's wafer-level length is smaller than the target length of the respective pillar by less than 20% of the target length of the respective pillar.

16. The method of claim 13 wherein a target distance between any two adjacent pillars in a direction of the pillars' widths is one to three times as large as the adjacent pillars' largest target width; and
a target distance between any two adjacent pillars in a direction of the pillars' lengths is one to three times as large as the adjacent pillars' largest target length.

17. The method of claim 13 wherein the target width and length of each pillar are each in a range of 130 nm to 180 nm, each first feature's wafer-level width is smaller than the target width of the respective pillar by at least 20 nm, and each first feature's wafer-level length is smaller than the target length of the respective pillar by at least 20 nm.

18. The method of claim 13 wherein said light is provided to said mask at a first exposure dose smaller than a best exposure dose needed to form pillars with an optical mask having the first features' wafer-level sizes equal to the target sizes of the respective pillars.

19. The method of claim 18 wherein the first exposure dose is smaller than said best exposure dose by at least 10% of said best exposure dose.

20. The method of claim 19 wherein the first exposure dose is smaller than said best exposure dose by at least 20% of said best exposure dose.

21. The method of claim 13 wherein the wavelength λ is at most 248 nm.

22. The method of claim 13 wherein the wavelength λ is at most 193 nm.

23. The method of claim 13 wherein the feature array is rectangular.

24. The method of claim 13 wherein each first feature is rectangular.

25. A method for photolithographically patterning photosensitive material with light comprising a wavelength λ to which the material is sensitive, to form a pillar array in the photosensitive material, the method comprising:
(a) obtaining an optical mask comprising a feature array which is an array of first features which are more transparent to said light than the optical mask's portion between the first features, wherein each said first feature's wafer-level width and length are below the wavelength λ, and wherein a combined area of the first features is smaller than the feature array's area between the first features;
(b) illuminating the photosensitive material with said light passing through the optical mask to project each first feature onto a site of a respective one of said pillars, the light causing the photosensitive material at the pillars' sites to become resistant to a developing operation developing the photosensitive material; and then
(c) performing the developing operation to remove at least part of the photosensitive material from between the pillar sites thus forming said pillars.

26. The method of claim 25 wherein the wavelength λ is at most 248 nm.

27. The method of claim 25 wherein a distance between adjacent first features in a direction of the first features' widths is one to three times as large as the adjacent first features' widths; and
a distance between adjacent first features in a direction of the first features' lengths is one to three times as large as the adjacent first features' lengths.

28. The method of claim 25 wherein the feature array is rectangular.

29. The method of claim 25 wherein each first feature is rectangular.
